(19) United States
(12) Patent Application Publication
(10) Pub. No.: US 2006/0210886 A1
(43) Pub. Date: Sep. 21, 2006

(54) Method for making grayscale photo masks and optical grayscale elements

(75) Inventors: Yosuke Mizuyama, Cambridge, MA (US); Xinbing Liu, Acton, MA (US)

Correspondence Address: STEVENS DAVIS MILLER & MOSHER, LLP, 1615 L STREET, NW, SUITE 850, WASHINGTON, DC, 20036, US

(73) Assignee: MATSUSHITA ELECTRIC INDUSTRIAL CO., LTD., Osaka (JP)

(21) Appl. No.: 11/083,324

(22) Filed: Mar. 18, 2005

(51) Int. Cl. G09B 7/00; G03C 5/00; G03F 1/00

(52) U.S. Cl. 430/5; 430/322; 430/323; 434/324

(57) ABSTRACT

A positive photo resist is provided on a surface of a photo mask blank. Light is then exposed onto the photo resist to form a predetermined pattern of unexposed and exposed portions in the photo-resist. After development, the exposed portions are removed and ions are implanted to obtain a modulated ion density in the photo mask blank. The implanted ions become color centers which absorb a specific wavelength of light and the modulated distribution of the color substrates create the grayscale photo mask. The photo resist structure is finally removed to produce a grayscale photo mask.

### BACKGROUND OF THE INVENTION

The present invention is directed to methods for making grayscale photo masks, and methods for making grayscale optical elements using the grayscale photo masks. Examples of the grayscale optical elements include refractive, reflective, and diffractive optical elements such as micro lenses, holograms and gratings.

Newly emerging optical disc formats such as Blu-Ray discs (BD) and High-Density discs (HD) use a blue laser having a 405 nm wavelength in order to focus the laser beam with great precision and tightly pack a large amount of data onto the disc. However, in contrast to the longer wavelengths used for the previous generation of optical discs such as DVD having a 680 nm wavelength, the shorter wavelengths have a lower photo-electron transformation and the reflectance of the reflective coatings provided on the traditional optical elements tend to be insufficient for the shorter wavelength.

As a result of the aforementioned characteristics of shorter wavelengths of light, grayscale optics have recently been the subject of great interest since they are able to provide higher efficiencies to compensate for the lower amounts of laser energy. The term grayscale optics is typically used to refer to micro-optics produced using a photolithographic process while the term ordinary optics is typically used to refer to optics produced using molding techniques or other mechanical methods such as a machining process.

Over the past ten years, various methods have been proposed for producing grayscale optics. For example, a direct method using a focused ion beam (FIB) has been proposed to fabricate a micro-lens (JP63-177509). However, such a method is not very cost effective since fabrication on a lens-by-lens basis is required and since emission of a FIB requires the use of very expensive equipment.

Another direct writing method which has been proposed is to emit an electron beam at an electron sensitive resist to make a micro-Fresnel lens (JP58-210765). However, this method is also expensive. In another method, a binary structure is first prepared in a photo resist and then ion beam etching is performed using a slant angle to make a blazed grating (JP54-119526). However, according to this particular method, blazed gratings having non-uniform and arbitrary structures are difficult to produce.

Yet another method proposed is a stamping method in which a mold is fabricated by a mechanical machining procedure and the machined structure is then transferred to an optical material (JP6-306321). However, in this particular method, the resolution of the microstructure has a drawback in that it is restricted by the nature and characteristics of the transferred material.

A multi-masking method and a grayscale photo mask method have been proposed as photolithographic methods. The multi-masking method is based on the usage of a binary mask and performing multiple exposures, development and etching (JP3-312655). In the grayscale photo mask method, since the photo mask is made to be a grayscale photo mask, the process is completed in one step. In general, the mask is used in a mask aligner or stepper and mass production of elements are performed by using a step-and-repeat process.

One type of such a grayscale photo mask is a “half tone” type in which a pixel in a photo mask is divided into plural sub-pixels and a rate of opening for an aperture (each sub-pixels have 0/1 binary transmittance) determines the transmission of the exposure light (U.S. Pat. No. 5,482,800). In this method, the resolution of the pattern is limited by a size of the sub-pixels which generally cannot be made very small.

Another type of the grayscale photo mask is a “surface relief type” in which the absorbing layer for exposure light has a surface structure and the intensity of the transmitted light is modulated corresponding to the thickness of the structure (U.S. Pat. No. 6,420,073 & U.S. Pat. No. 6,613,498). This type of photo mask is fragile and not durable for performing a step-and-repeat process because the surface structure is generally a microstructure which is prone to damage by even slight contact or by mishandling. Another type of grayscale photo mask is a “density type” in which the density of the absorbing layer for the exposure light is made to be varied over a photo mask. This type of photo mask is relatively stable and is durable for general usage (U.S. Pat. No. 6,638,667 & U.S. Pat. No. 6,562,523). In practice, the method disclosed in U.S. Pat. No. 6,562,523 provides the only practical density type grayscale photo mask. However, this disclosed method completely depends on the use of a specific type of glass that is generally not easy to make, thereby prohibiting this method from being cost effective. Particularly, the glass is made from a base glass component mixed with some metal oxides which are then ion-exchanged in a solution to exchange the metal ions in the metal oxides with silver ions. To write a pattern, an electron beam writer is required that can modulate the dosage of electrons.

### SUMMARY OF THE INVENTION

An object of the present invention is to provide practical methods for making a density type of grayscale photo mask that has a capability of providing a high resolution with desired characteristics and that can be produced at a low cost, and to provide methods for making grayscale optical elements using such grayscale photo masks.

According to the present invention, a method is provided for producing a grayscale photo mask by: providing a photo resist on a surface of a photo mask blank; exposing grayscale light onto the photo resist to form a predetermined pattern of exposed and unexposed portions in the photo resist; developing the photo resist to remove the exposed portions in the photo resist and produce a grayscale photo resist; implanting ions into and through the grayscale photo resist to obtain a modulated ion density in the photo mask blank; and removing the grayscale photo resist.

According to another aspect of the present invention, a method is provided for producing a grayscale photo mask by: providing a photo resist on a surface of a photo mask blank; exposing grayscale light onto the photo resist to form a predetermined pattern of exposed and unexposed portions in the photo resist; developing the photo resist to remove the exposed portions in the photo resist and produce a grayscale photo resist structure; performing one of ion beam milling and etching to transfer the grayscale photo resist structure into the photo mask blank; implanting ions into the photo mask blank to obtain a modulated ion density in the photo mask blank; and removing portions of the photo mask blank containing the transferal of the grayscale photo resist structure.

According to another aspect of the present invention, a method is provided for producing an optical grayscale element by: providing a first photo resist on a surface of a photo mask blank; exposing grayscale light onto the first photo resist to form a predetermined pattern of exposed and unexposed portions in the first photo resist; developing the first photo resist to remove the exposed portions in the first photo resist and produce a grayscale photo resist; implanting ions into and through the grayscale photo resist to obtain a modulated ion density in the photo mask blank; removing the grayscale photo resist to obtain the grayscale photo mask; providing a second photo resist on a surface of a substrate; placing the grayscale photo mask in close proximity to the second photo resist; exposing light onto and through the grayscale photo mask to transfer the modulated ion density contained in the grayscale photo mask into the second photo resist as exposed and unexposed portions; developing the second photo resist to remove the exposed portions in the second photo resist; and performing one of etching and ion beam milling to the second photo resist and photo mask blank to obtain the optical grayscale element.

According to another aspect of the present invention, a method is provided for producing an optical grayscale element by: providing a first photo resist on a surface of a photo mask blank; exposing grayscale light onto the first photo resist to form a predetermined pattern of exposed and unexposed portions in the first photo resist; developing the first photo resist to remove the exposed portions in the first photo resist and produce a grayscale photo resist structure; performing one of ion beam milling and etching to transfer the grayscale photo resist structure into the photo mask blank; implanting ions into the photo mask blank to obtain a modulated ion density in the photo mask blank; removing portions of the photo mask blank containing the transferal of the grayscale photo resist structure to produce the grayscale photo mask; providing a second photo resist on a surface of a substrate; placing the grayscale photo mask in close proximity to the second photo resist; exposing light onto and through the grayscale photo mask to transfer the modulated ion density contained in the grayscale photo mask into the second photo resist as exposed and unexposed portions; developing the second photo resist to remove the exposed portions in the second photo resist; and performing one of etching and ion beam milling to the second photo resist and photo mask blank to obtain the optical grayscale element.

According to the various aspects of the invention mentioned above, exposing of the grayscale light is performed using a grayscale direct writer.

According to the various aspects of the invention mentioned above, exposing of the grayscale light is performed using a focused laser writer.

According to the various aspects of the invention mentioned above, the removing of the grayscale photo resist is performed by stripping away the grayscale photo resist.

According to the various aspects of the invention mentioned above, the ions used for implantation are selected based on performing the exposure of light onto and through the grayscale photo mask using light having a wavelength which is one of 436 nm (G-line), 405 nm (H-line), 365 nm (I-line), 248 nm (KrF excimer laser), 193 nm (ArF excimer laser), and 0.71 nm (X-ray).

According to the various aspects of the invention mentioned above, implanting of the ions is performed by implanting a dosage of ions in a range of 10¹⁵ to 10¹⁸ atoms/cm².

According to the various aspects of the invention mentioned above, implanting of the ions is performed by using an incident angle of implantation that is in a range of 5° to 10° with respect to a normal.

According to the various aspects of the invention mentioned above, providing the photo resist is performed by providing a positive type photo resist.

According to the various aspects of the invention mentioned above, the removal of portions of the photo mask blank containing the transferal of the grayscale photo resist is performed by polishing.

According to the various aspects of the invention mentioned above, the exposing of light onto and through the grayscale photo mask is performed using one of a mask aligner and stepper.

According to the various aspects of the invention mentioned above, the etching is performed by one of a dry etching method and a wet etching method.

According to the various aspects of the invention mentioned above, an element having at least an atomic number which provides no greater than a maximum allowable RMS radial expansion for achieving a desired resolution of the grayscale photo mask is selected as the ion for implantation.

### BRIEF DESCRIPTION OF THE DRAWINGS

The above and other objects, features, and advantages of present invention will be more clearly understood from the following detailed description taken in conjunction with the accompanying drawings, in which:

FIGS. 1A is a diagram illustrating the penetration of ions into a mask blank, and FIG. 1B is a diagram depicting a modulation of exposure light using an ion implanted mask blank;

FIG. 2A is a flow diagram illustrating a first method for producing a grayscale photo mask according to the present invention, and FIG. 2B is a flow diagram illustrating a second method for producing a grayscale photo mask according to the present invention;

FIG. 3 is a flow diagram illustrating a method for producing a grayscale element according to the present invention;

FIG. 4 is a graph depicting a dynamic transmission range of a grayscale structure before and after ion implantation;

FIG. 5 is graph illustrating a transmission spectra of fused silica, Al, Ag, and C;

FIG. 6 is a diagram depicting a cross sectional view of ion penetration into a mask blank provided with a saw tooth shaped grayscale structure;

FIGS. 7A-7D are graphs showing the relationships between the thickness, penetration depth of ions, transmittance; and optical density, respectively, for a grayscale structure;

FIG. 8A is a graph illustrating the incident angle of ions during implantation, and FIGS. 8B to 8F are graphs illustrating the penetration depth of ions for silver, silicon, nickel, carbon, and aluminum, respectively;

FIG. 9 is a graph illustrating the penetration depth of ions for different materials used for the grayscale structure; and

FIG. 10 is a graph illustrating the penetration depth of ions for different incident angles of ion implantation.

FIGS. 11A-11D are graphs showing the RMS radial expansion for various types of ions implanted with acceleration voltages of 200 kV, 150 kV, 100 kV, and 50 kV, respectively.

### DETAILED DESCRIPTION

According to the present invention, absorbing centers are embedded in a transparent mask blank material by ion implantation through a suitable grayscale structure that controls the penetration of the color centers (implanted ions). The implanted ions in the substrate become the color centers which absorb a specific wavelength of light. As a result of this process, the distribution of the absorbing centers over the mask blank surface is modulated corresponding to the grayscale structure to create a grayscale photo mask.

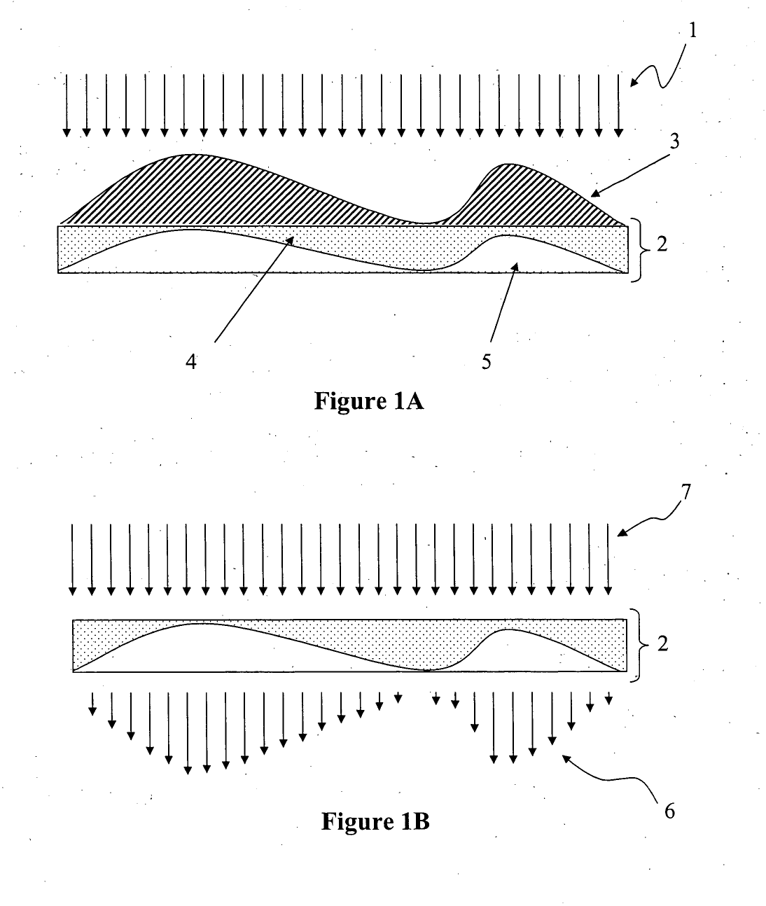

FIG. 1A illustrates the manner in which ions emitted in a flat ion beam 1 towards a grayscale structure 3 penetrate into a mask blank 2. As shown in FIG. 1A, the penetration depth of the ions in an ion penetrated portion 4 of the mask blank 2 corresponds to a depth of the grayscale structure 3. Particularly, as shown in FIG. 1A, the penetration depth of the ions into the mask blank 2 corresponding to the shallower portions of the grayscale structure 3 is greater than the penetration depth of ions into the mask blank 2 corresponding to the deeper portions of the grayscale structure 3. Moreover, as further shown in FIG. 1A, as the depth of the grayscale structure 3 is varied across the mask blank 2, the penetration depth of the ions in the mask blank 2 is correspondingly varied across the mask blank 2 as can be realized by examining the ion penetrated portion 4 of the mask blank 2 and the non-penetrated portion 5 of the mask blank 2.

As shown in FIG. 1B, upon removal of the grayscale structure 3 shown in FIG. 1A, implanted ions having a modulated thickness of penetration are left in the resultant mask blank 2, thereby providing a grayscale photo mask 2 in which a transmission of light 6 resulting from a flat exposure of light 7 emitted from an exposure equipment (not shown), such as a mask aligner or stepper, is modulated.

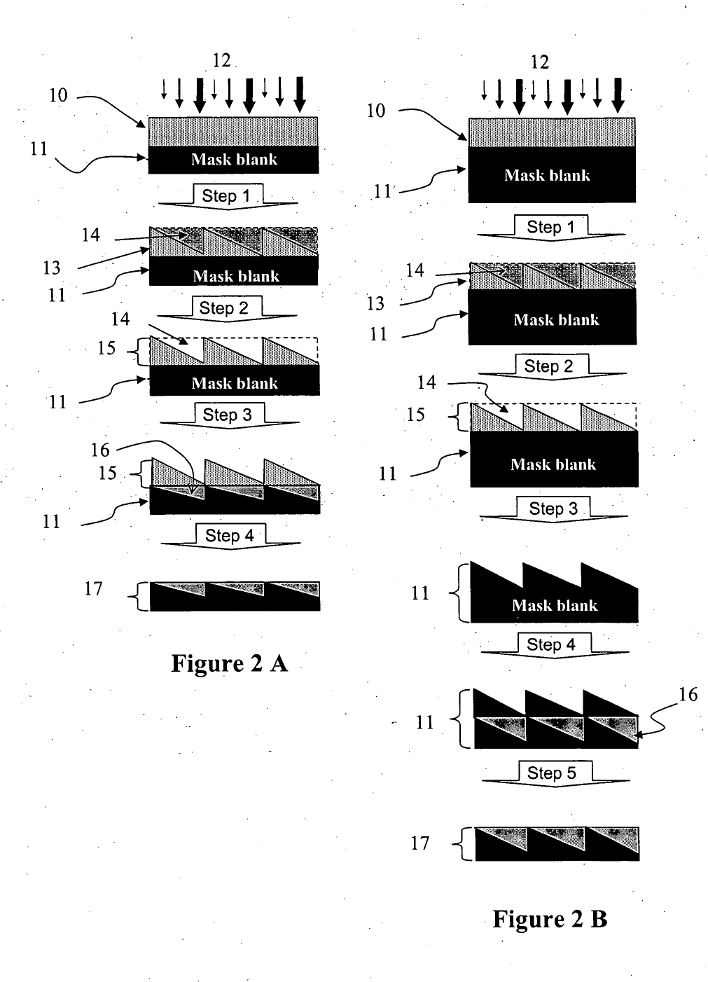

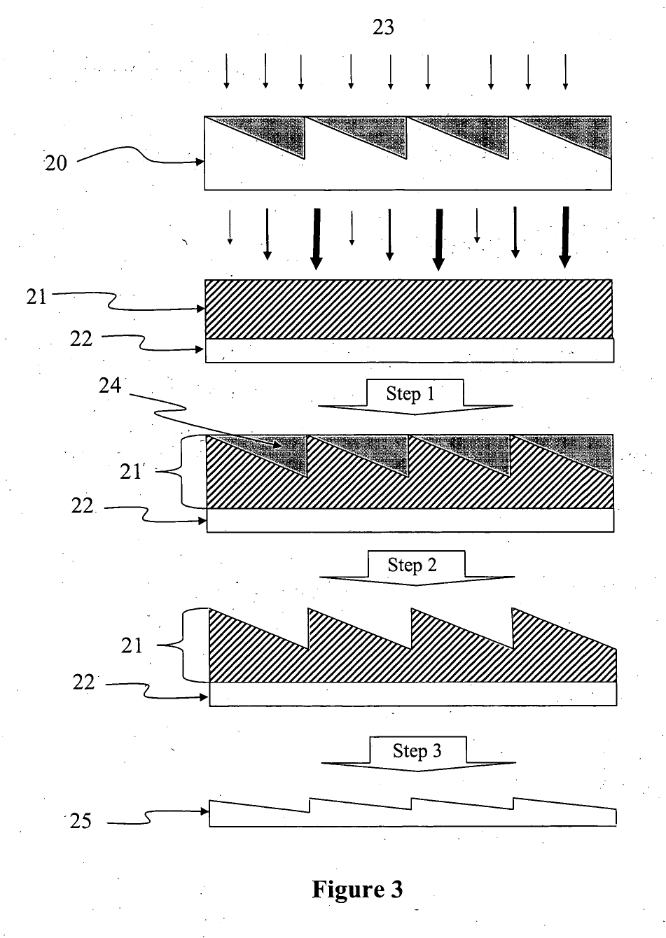

Provided next is a description of the methods of the present invention for producing a grayscale element with reference to FIG. 2A which depicts a first method for making a grayscale photo mask, FIG. 2B which depicts a second method for making a grayscale photo mask, and FIG. 3 which depicts a method for making a grayscale optical element by using a grayscale photo mask produced according to either of the first or second methods.

As shown in FIG. 2A, according to the first method for making a grayscale photo mask according to the present invention, a positive photo resist 10 is provided on the photo mask blank 11 and grayscale exposure 12 is performed using, for example, a relatively inexpensive direct grayscale laser writer to from a desired pattern of exposed 14 and unexposed 13 portions in Step 1. The grayscale exposure 12 can also be performed using a focused laser writer which includes, for example, a 440 nm He—Cd laser or a 405 nm semiconductor laser. Next, in Step 2, development is performed such that the exposed portions 14 of the photo resist are removed such that all that is left are the unexposed portions 13 of the photo resist, thereby producing a grayscale photo resist structure 15. Next, ion implantation is performed in Step 3 by, for example, implanting a flat ion beam into and through the grayscale photo resist structure 15 to obtain a modulated ion density 16 in the photo mask 11. In Step 4, the grayscale photo resist structure 15 is stripped away to obtain a final grayscale photo mask 17.

FIG. 2B shows the second method for making the grayscale photo mask according to the present invention. The first two steps of the second method are the same as the first two steps of the first method. According to the third step of this second method, ion beam milling is performed to transfer the grayscale photo resist structure 15 into the photo mask blank 11. Next, ion implantation is performed in Step 4 by, for example, implanting a flat ion beam into the photo mask 11 to obtain a modulated ion density 16 in the photo mask blank 11. Finally in Step 5, the portion of the photo mask blank 11 containing the transferal of the grayscale photo resist.structure is polished away to obtain a grayscale photo mask 17.

FIG. 3 depicts an exemplary procedure for making a grayscale element 25 using a grayscale photo mask 20. It is initially noted that the grayscale photo mask 20 used for making the grayscale element 25 can be produced using either the first or second methods described above and shown in FIGS. 2A and 2B, respectively. In Step 1, a photo resist 21 is provided on a substrate 22 that is to be made into the final grayscale element and light 23 is exposed 23 onto and through the grayscale photo mask 20 using a mask aligner or stepper to transfer the grayscale structure from the grayscale photo mask 20 into the photo resist 21. Subsequently, development is performed in Step 2 to remove the exposed portions 24 of the photo resist 21 such that all that is left are the unexposed portions of the photo resist 21. In Step 3, etching is performed using any appropriate etching method such as, for example, a dry etching method including RIE (Reactive Ion Etching) or wet etching using a suitable etchant solution or other method such as ion beam milling to thereby produce the grayscale element 25.

Provided next is a description of various factors and characteristics to be taken into account in the aforementioned methods for making a desired grayscale photo mask according to the present invention.

One of these factors is the absorption spectrum of the photo mask blank. The absorption spectrum of the photo mask blank will vary depending on the particular type of ion implanted into the photo mask blank. Additionally, the use of different wavelengths of light for exposure onto and through the grayscale photo mask will result in different levels of absorbance. According to the present invention, the specific wavelength of an exposure light produced by a mask aligner or stepper is of particular interest. The exposure light requires modulation in order to achieve a desired grayscale exposure. The currently available exposure wavelengths are 436 nm (G-line), 405 nm (H-line), 365 nm (I-line) from a Mercury lamp, 248 nm from KrF excimer laser, 193 nm from ArF excimer laser and 0.71 nm from X-ray. In order to assure a proper and desired quality of ion implantation, a particular dynamic range of absorption of the photo mask blank is required. Accordingly, the ions used for implantation are selected based on performing the exposure of light onto and through the grayscale photo mask using light having a wavelength which is one of 436 nm (G-line), 405 nm (H-line), 365 nm (I-line), 248 nm (KrF excimer laser), 193 nm (ArF excimer laser), and 0.71 nm (X-ray).

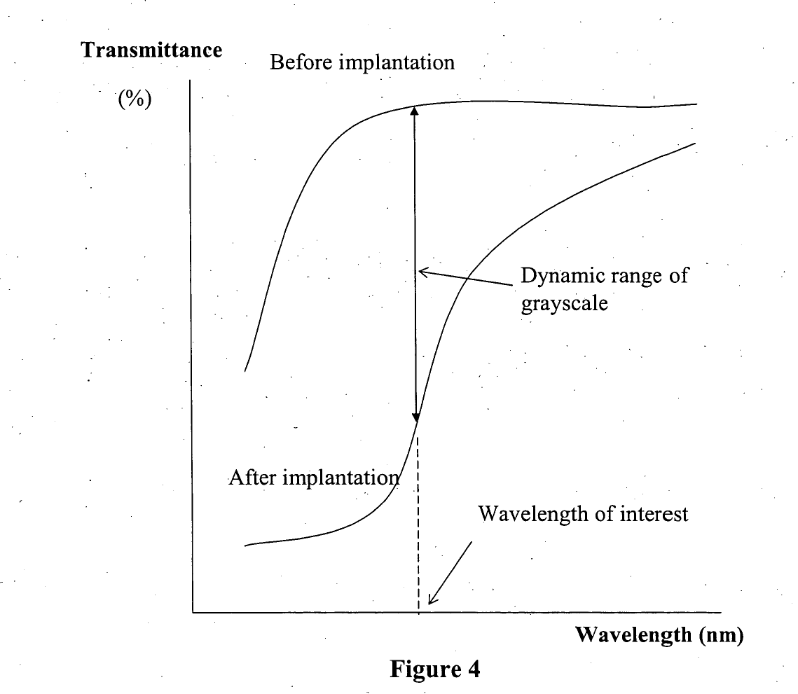

FIG. 4 is a graph showing the transmittance versus the wavelength of light exposed to a grayscale element. As illustrated by this graph, there exists a dynamic range of transmittance for a particular wavelength. This dynamic range for a desired grayscale element exists in a gap between the transmittance prior to implantation of ions and the transmittance after implantation of ions. An absolute optical density and a relative optical density used to characterize the absorption/transmission of exposure light are expressed as follows:

Absolute Optical Density (dₐ)
dₐ=−Log₁₀T(λ)

wherein T is the absolute transmission at a wavelength λ.

Relative Optical Density (dr)
dᵣ=−Log₁₀(T(λ)/T₀(λ))

wherein T₀ is the absolute base transmission at a wavelength λ.

Table 1 provided below contains exemplary calculations for demonstrating the relationships of the absolute optical density and the relative optical density for a base transmission of 85%. As apparent from Table 1, the absolute and relative optical densities increase as the transmission decreases.

TABLE 1

| % Transmission | Absolute OD | Relative OD |
|---|---|---|
| 100 | 0.00 | N/A |
| 85 | 0.07 | 0.00 |
| 10 | 1.00 | 0.93 |
| 8.5 | 1.07 | 1.00 |
| 1 | 2.00 | 1.93 |
| 0.85 | 2.07 | 2.00 |
| 0.1 | 3.00 | 2.93 |
| 0.085 | 3.07 | 3.00 |

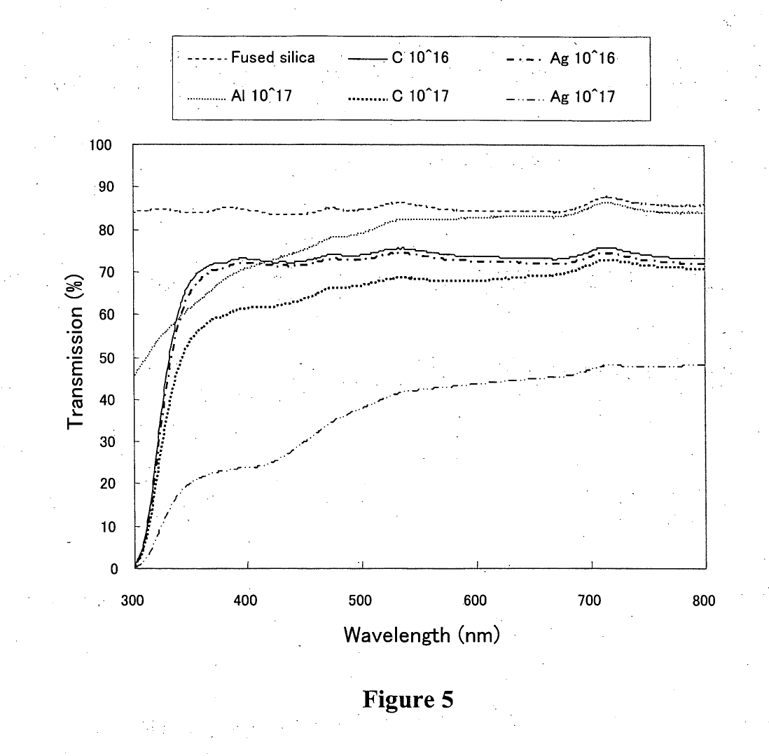

FIG. 5 is a graph illustrating the transmittance of various states of a fused silica substrate versus the wavelength of light exposed to the substrate. The graph depicts a fused silica substrate which has been implanted using a known BARIAN VII Sta series implanter produced by Varian Semiconductor Equipment. It is noted that other implanters can also be used such as one available from Sumitomo Eaton Nova Corporation (NV series implanter). A base transmittance of approximately 85% for the bare mask blank (fused silica) without being subjected to implantation is. shown by line labeled as “Fused silica”. The remaining lines correspond to the transmittance of the mask blank after implantation with 10¹⁷ atoms per cm² of Al, and 10¹⁶ and 10¹⁷ atoms per cm² of each of C and Ag.

Upon comparison of the transmittance of the fused silica without ion implantation and the transmittance of Ag and C implanted with ions in FIG. 5, it is readily apparent that the transmission generally drops for the implanted mask when examining the range of the wavelengths. This drop provides evidence of the absorption by implanted ions in the mask. The magnitude of the absorption is proportional to the dosage of implantation. Thus, FIG. 5 makes it clear that a large optical density can be achieved around 300 nm if C and Ag are used. Moreover, the graph further illustrates that a high optical density can also be achieved by increasing the dosage of the implanted ions for the remaining wavelength ranges.

Without paying consideration to situations in which a desired resolution of the grayscale photo mask is required (this will be described later), the particular type of ion used for implantation is not a critical factor and any ion can generally be used. For example, the following ions can be used: H, He, Li, Be, B, C, N, O, F, Ne, Na, Mg, Al, Si, P, S, Cl, Ar, K, Ca, Ti, V, Cr, Mn, Fe, Co, Ni, Cu, Zn, Ga, Ge, As, Se, Br, Kr, Rb, Sr, Y, Zr, Nb, Mo, Rh, Rd, Ag, Cd, In, Sn, Sb, Te, I, Xe, Ba, La, Hf, Ta, W, Ir, Pt, Au, Ce, Pr, Nd, Sm, Eu, Tb, and Er. The ions are typically implanted using a commercial ion implanter with several hundreds kilo-volts of power and are usually implanted using a slanted incident angle. A dosage of the implanted ions is proportional to an amount of time spent for the implantation operation. The dosage of ions typically falls within a range of approximately 10¹⁵ and 10¹⁸ atoms/cm² and is dependent on the amount of optical density required.

The discussion will now focus on the manner in which a particular grayscale structure is designed after the maximum optical density has been obtained. FIG. 6 illustrates an example for obtaining a saw tooth profile structure in the grayscale structure 10. When ions are implanted over a saw-tooth grayscale structure (for example, a saw-tooth profiled photo resist) using a flat ion beam 1, ions penetrate linearly depending on the thickness of the grayscale structure 10 and on the particular material used for the mask blank 9. Thus, as can be realized from the implanted portion 12 of the mask blank 9 shown in FIG. 6 where ions have penetrated, the maximum penetration 13 (maximum optical density) occurs where the grayscale structure has a minimum thickness 14 and the minimum penetration 15 occurs where the grayscale structure 10 has a maximum thickness 16.

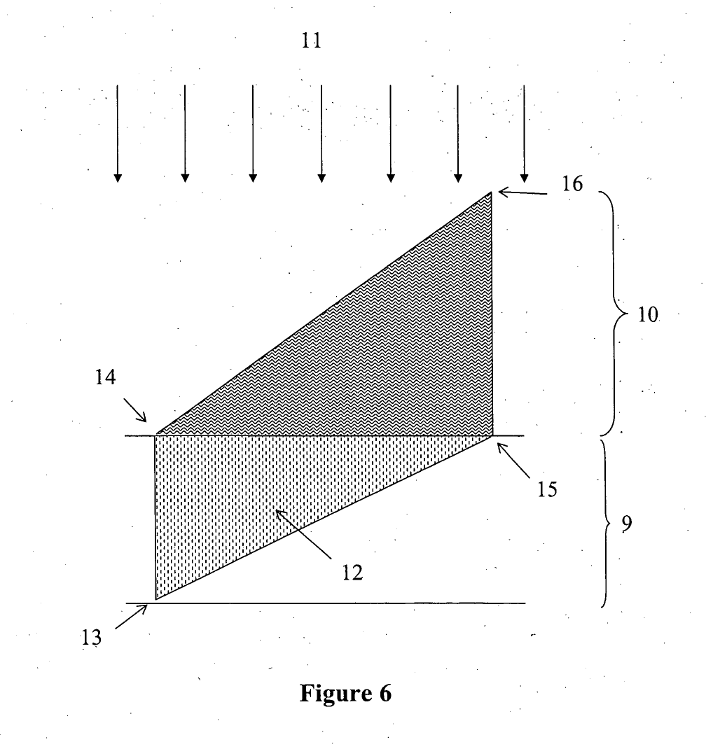

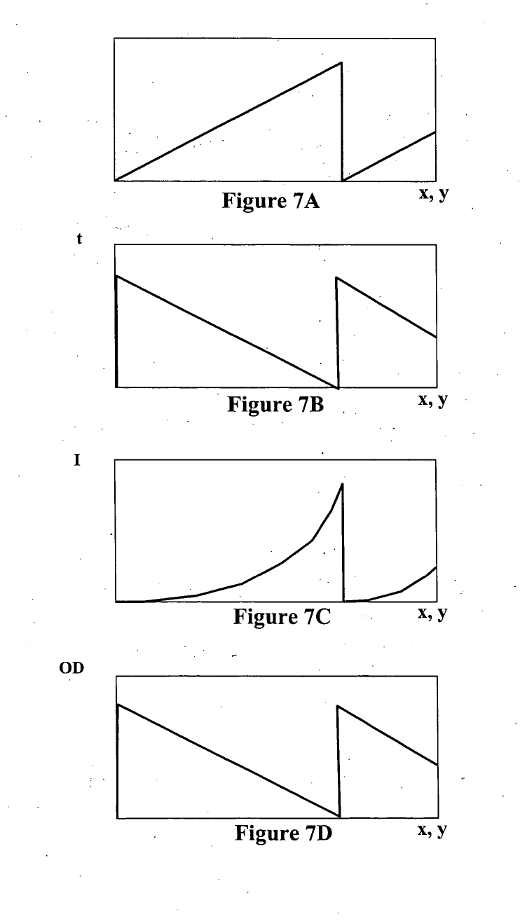

FIGS. 7A-7D and the corresponding functions (A)-(D) provided below, respectively, illustrate the relationships between the thickness of the grayscale structure on the mask blank, the penetration depth of the ions, the transmittance of light, and corresponding optical density:
(A) SURFACE PROFILE of grayscale structure: Z=d(x,y)
(B) PENETRATION DEPTH: t=g(x,y);
   where g has a linear complementary relationship to d.
(C) TRANSMITTANCE: I=I₀exp(−At);
   where A is an extinction coefficient depending on the absorbing center.
(D) OPTICAL DENSITY: OD=−Log(I/I₀)=Ct;
   where C is a constant.
      By performing ion implantation simulations, the penetration depth has been confirmed to have a linear functional relationship with the surface height of the grayscale structure. Functions (A) and (D) above and FIGS. 7A and 7D clearly demonstrate that the surface profile of a grayscale structure and the optical density of the implanted substrate have a “linear positive-negative” relationship.

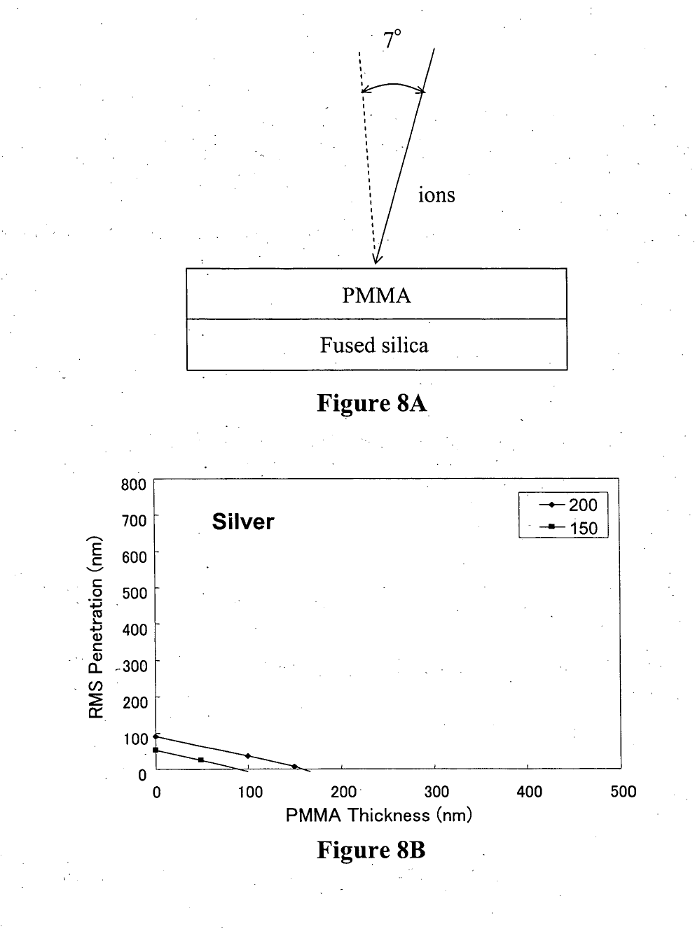

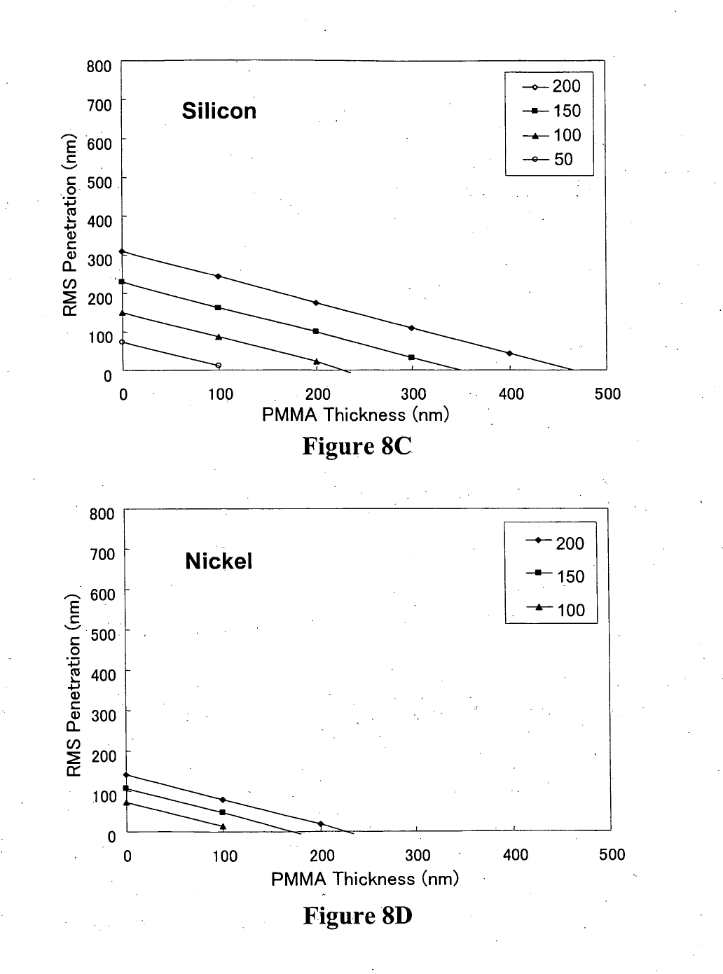

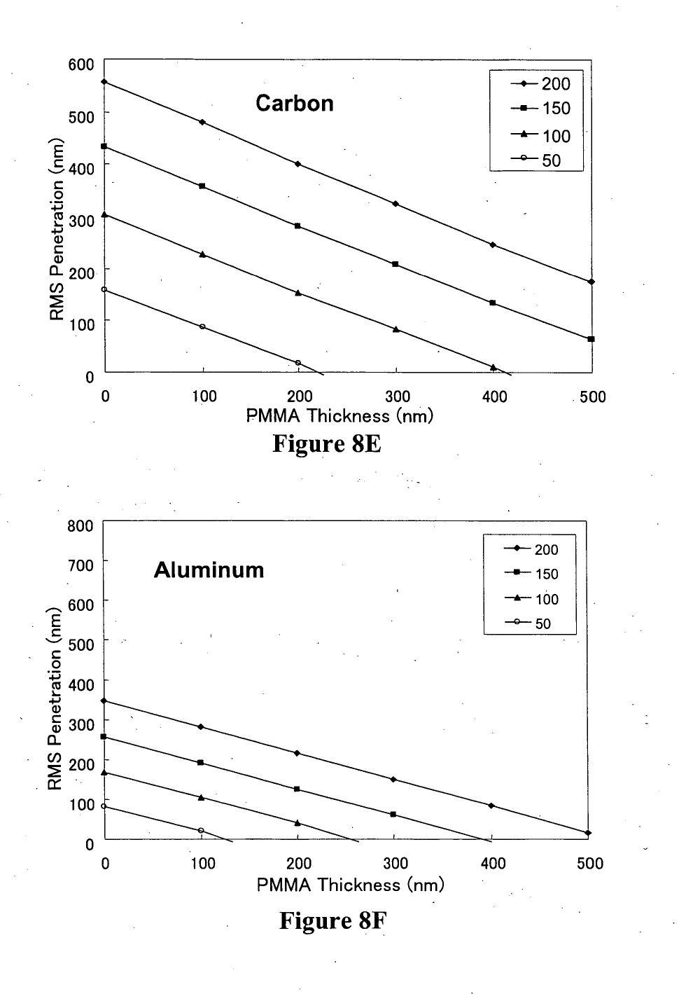

It has been determined that various factors affect the penetration depth of the ions. Such determinations were made using numerical experiments in which the penetration depth of ions were calculated using a Monte-Carlo based ion implantation simulator known as SRIM2000. The results of the numerical experiments conducted for Ag, Si, Ni, C, and Al are shown in FIGS. 8B-8F, respectively. As shown in FIG. 8A, the numerical experiments were performed using a PMMA (Polymethylmethacrylate) photo resist material as a test material placed on a fused silica mask blank, and ion beams were emitted to strike these materials at a slant angle of 720 from a normal on the PMMA side.

As shown in FIGS. 8B-8F, each of the five elements Ag, Si, Ni, C, and Al, respectively, were tested with an acceleration voltage ranging from 50 kV to 200 kV, and the resulting RMS (Root Mean Square) penetration depths versus PMMA thicknesses are depicted. The first notable characteristic apparent from FIGS. 8B-8F is that the RMS penetration depth of ions is linear to the thickness of the PMMA.

As further evidence of the first notable characteristic mentioned above, an experiment was conducted in which a carbon ion beam was emitted at 100 kV towards the saw-tooth structure shown in FIG. 6, and a penetration depth of 300 nm at the maximum penetration portion 13 was achieved. However, the ions did not penetrate at all at the maximum thickness portion 16 which was 400 nm. Moreover, the carbon ions provided a 0.84% transmission (relative optical density =2.0) for a 300 nm wavelength when implanted while the original transmission is 84%. Thus, it is possible to obtain a grayscale (saw-tooth) optical density with a 400 nm grayscale structure and carbon implantation over the structure.

A second notable characteristic is that the smaller the atomic weight, the higher the magnitude of penetration. For example, for the same PMMA and the same acceleration voltage of 200 kV, the penetration depth of Si (atomic weight=28) is three times higher than the penetration depth of Ag (atomic weight=108). It is noted that a ratio of these different penetration depths roughly corresponds to a ratio of the different atomic weights.

Another characteristic is that the acceleration voltage has a linear relationship with the penetration depth. Accordingly, it is possible to select a heavier atom by increasing the acceleration voltage. Moreover, if it is desired to double the thickness of the grayscale structure, this can be achieved by doubling the acceleration voltage.

The decision of which particular ion to select can be determined based upon the required optical density and the required transmission at the wavelength of exposure light to be used. For example, when I-line exposure is to be used, Ag is a suitable candidate for use as the emitted ion since it is most absorptive for the I-line exposure. If an optical density of 1.0 is needed, a transmission of 8.5% is required and a dosage slight larger than 10¹⁷ atom/cm² is required. However, it is noted that the dosage does not have to reach 10¹⁸ atom/cm² in this case. The maximum thickness of PMMA is about 150 nm for Ag. For example, it is possible to make a saw-tooth grayscale structure having an optical density in the range of 0 to 1.0 using Ag ion implantation with 200 kV and with a grayscale PMMA having a maximum thickness of 150 nm. If it is difficult to make the grayscale PMMA having a thickness of 150 nm then, as mentioned earlier, the acceleration voltage can be increased above 200 kV to obtain an increase in the thickness of the grayscale PMMA.

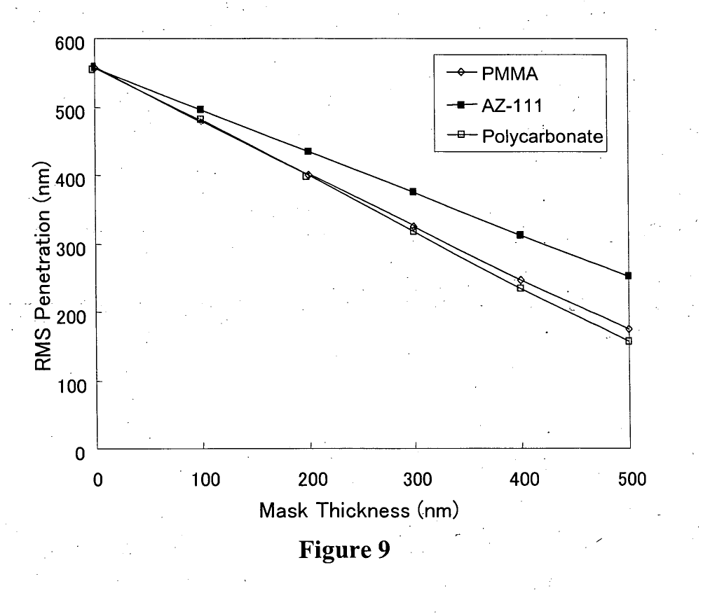

The selection of a particular material for use as the grayscale structure is another factor which affects the magnitude of penetration depth. While any positive type photo resist can be used such as, for example, PMMA base photo resist, Shipley SC 1827, Shipley S1813, AZ-111 photo resist produced by AZ Materials, or any other positive photo resist of a series of AZ photo resists, the penetration depth of ions is considerably different depending on the particular grayscale material which is used. For example, as shown in FIG. 9, the use of AZ-111 provides the greatest penetration depth when compared to polycarbonate and PMMA. As further shown in FIG. 9, the use of AZ-111 provide an RMS penetration which is approximately as much as 100 nm greater than polycarbonate and PMMA.

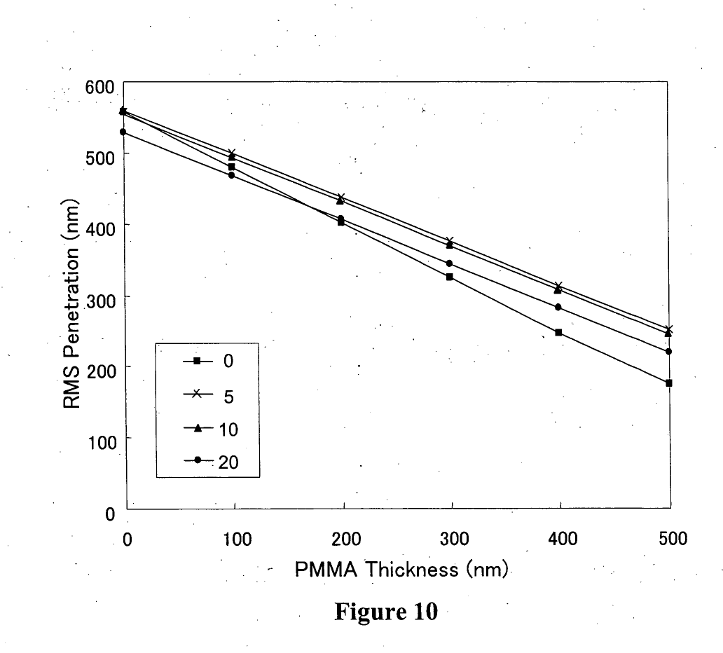

Next, another characteristic which affects the penetration depth is the incident angle of implantation as shown in FIG. 10. Although the maximum penetration can be obtained by using an incident angle of approximately 7 degrees from a normal of the target substrate, there may be situations in which other angles falling in the range of 5-10 degrees may be desired.

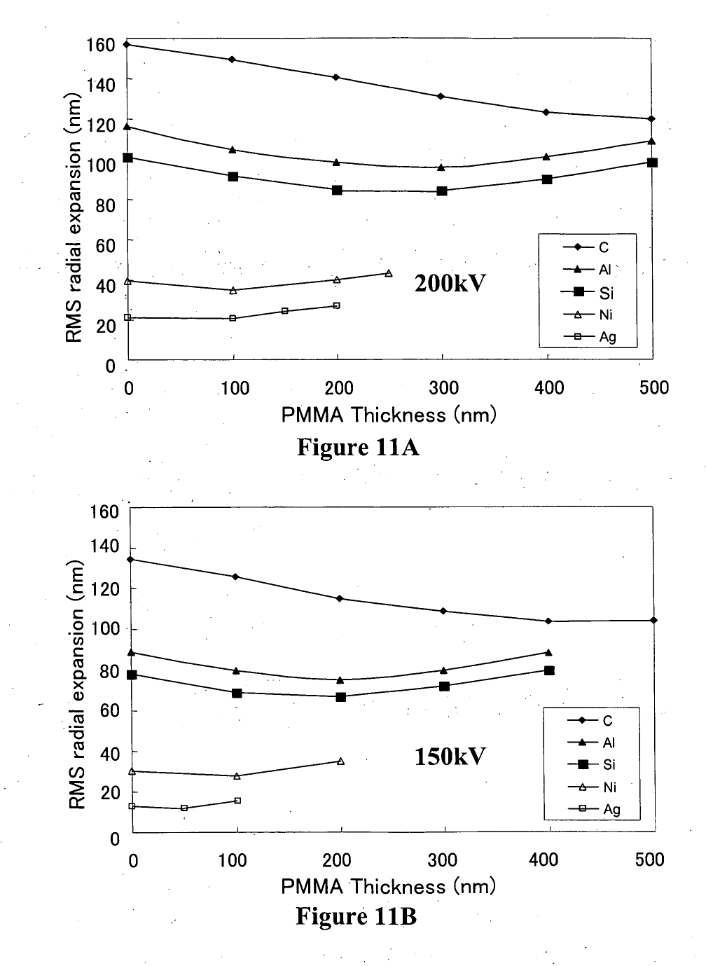

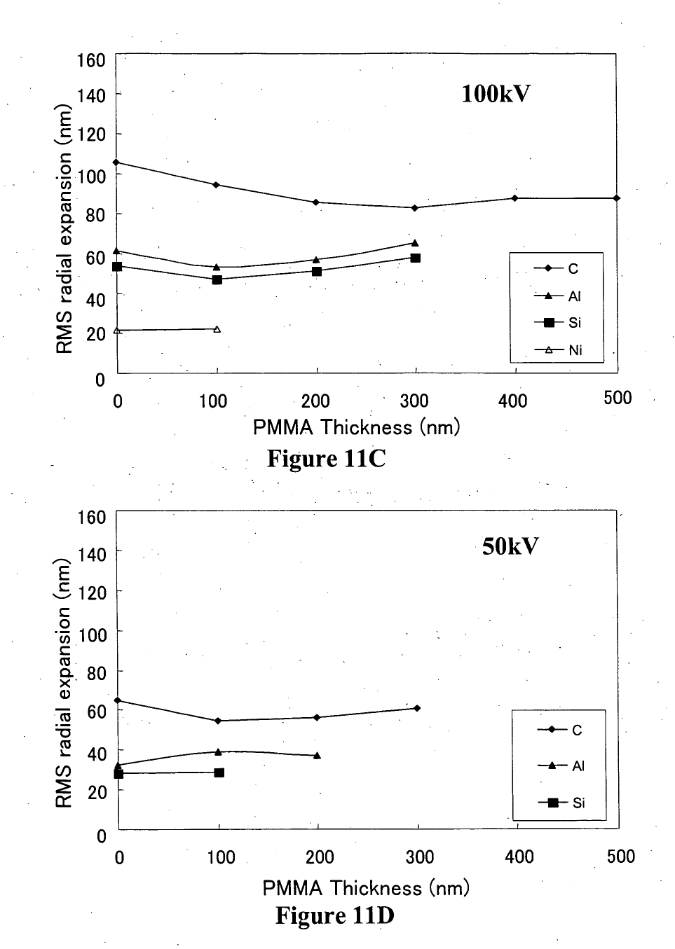

The resolution of a grayscale photo mask is affected by a phenomenon known as “random walk” which occurs after implantation of the ions when making the grayscale mask. Particularly, random walk defines the movement of ions after being implanted through the surface of a material. FIGS. 11A-11D depict the RMS radial expansion for various types of ions implanted with acceleration voltages of 200 kV, 150 kV, 100 kV, and 50 kV, respectively. As can be realized by FIGS, 11A-11D depicting C (atomic number 6), Al (atomic number 13), Si (atomic number 14), Ni (atomic number 28), and Ag (atomic number 47), the lighter ions expand more than the heavier ions and the distance of such random walk movement is proportional to an inverse of the atomic number of the ion. Consequently, as the atomic number of the ions decrease, the RMS expansion increases, and the resolution of a resultant grayscale photo mask decreases. Accordingly, it is preferable to use heavier ions for implantation such as Ni and Ag. Thus, when a desired resolution of the grayscale photo mask is required, it is necessary to select, as the ion for implantation, an element having at least an atomic number which provides no greater than a maximum allowable RMS radial expansion for achieving the desired resolution of the grayscale photo mask. For example, viewing FIG. 11A, if a desired resolution allows no greater than an RMS radial expansion of 60 nm, then either Ni, Ag, or any other element having an atomic number which provides no greater than an RMS radial expansion of 60 nm should be selected as the ion for implantation.

The foregoing description provides the details for preferred methods for making a grayscale photo-mask and grayscale optical element according to the present invention. Provided next is a description of an exemplary overall procedure for making a grayscale element. First, determination of the desired optical density is performed. Next, upon ascertaining the desired optical density, then a particular ion is selected that is appropriate for the optical density and the proper dosage of the ions is determined. Subsequently, the particular material for the grayscale structure and the particular method for making the grayscale structure are selected. Next, an appropriate acceleration voltage is determined which enables the grayscale structure to be constructed with a practically usable thickness. The grayscale structure is then formed using a preferred method of formation. Subsequently, the selected ion is implanted with the determined dosage and acceleration voltage. Lastly, the grayscale structure is removed by either being stripped off or being polished away to obtain the final grayscale element.

Although the preferred embodiments of the present invention have been described and disclosed for illustrative purposes, those skilled in the art will appreciate that various modifications, additions, and substitutions are possible without departing from the scope and spirit of the invention as set forth in the accompanying claims.

What is claimed is:

1. A method for producing a grayscale photo mask, said method comprising:
providing a photo resist on a surface of a photo mask blank;
exposing grayscale light onto the photo resist to form a predetermined pattern of exposed and unexposed portions in the photo resist;
developing the photo resist to remove the exposed portions in the photo resist and produce a grayscale photo resist;
implanting ions into and through the grayscale photo resist to obtain a modulated ion density in the photo mask blank; and
removing the grayscale photo resist.

2. A method for producing a grayscale photo mask as claimed in claim 1, wherein said exposing grayscale light is performed using a grayscale direct writer.

3. A method for producing a grayscale photo mask as claimed in claim 1, wherein said removing the grayscale photo resist is performed by stripping away the grayscale photo resist.

4. A method for producing a grayscale photo mask as claimed in claim 1, wherein said exposing grayscale light is performed using a focused laser writer.

5. A method for producing a grayscale photo mask as claimed in claim 1, wherein said implanting ions is performed by implanting a dosage of ions in a range of 10¹⁵ to 10¹⁸ atoms/cm².

6. A method for producing a grayscale photo mask as claimed in claim 1, wherein said implanting ions is performed by using an incident angle of implantation that is in a range of 5° to 10° with respect to a normal.

7. A method for producing a grayscale photo mask as claimed in claim 1, wherein said providing the photo resist is performed by providing a positive type photo resist.

8. A method for producing a grayscale photo mask as claimed in claim 1, further comprising selecting, as the ion for implantation, an element having at least an atomic number which provides no greater than a maximum allowable RMS radial expansion for achieving a desired resolution of the grayscale photo mask.

9. A method for producing a grayscale photo mask, said method comprising:
providing a photo resist on a surface of a photo mask blank;
exposing grayscale light onto the photo resist to form a predetermined pattern of exposed and unexposed portions in the photo resist;
developing the photo resist to remove the exposed portions in the photo resist and produce a grayscale photo resist structure;
performing one of ion beam milling and etching to transfer the grayscale photo resist structure into the photo mask blank;
implanting ions into the photo mask blank to obtain a modulated ion density in the photo mask blank; and
removing portions of the photo mask blank containing the transferal of the grayscale photo resist structure.

10. A method for producing a grayscale photo mask as claimed in claim 9, wherein said exposing grayscale light is performed using a grayscale direct writer.

11. A method for producing a grayscale photo mask as claimed in claim 9, wherein said removing portions of the photo mask blank containing the transferal of the grayscale photo resist is performed by polishing.

12. A method for producing a grayscale photo mask as claimed in claim 9, wherein said exposing grayscale light is performed using a focused laser writer.

13. A method for producing a grayscale photo mask as claimed in claim 9, wherein said implanting ions is performed by implanting a dosage of ions in a range of 10¹⁵ to 10¹⁸ atoms/cm².

14. A method for producing a grayscale photo mask as claimed in claim 9, wherein said implanting ions is performed using an incident angle of implantation that is in a range of 520 to 10° with respect to a normal.

15. A method for producing a grayscale photo mask as claimed in claim 9, wherein said providing the photo resist is performed by providing a positive type photo resist.

16. A method for producing a grayscale photo mask as claimed in claim 9, further comprising selecting, as the ion for implantation, an element having at least an atomic number which provides no greater than a maximum allowable RMS radial expansion for achieving a desired resolution of the grayscale photo mask.

17. A method for producing an optical grayscale element, said method comprising:
providing a first photo resist on a surface of a photo mask blank;
exposing grayscale light onto the first photo resist to form a predetermined pattern of exposed and unexposed portions in the first photo resist;
developing the first photo resist to remove the exposed portions in the first photo resist and produce a grayscale photo resist;
implanting ions into and through the grayscale photo resist to obtain a modulated ion density in the photo mask blank;
removing the grayscale photo resist to obtain the grayscale photo mask;
providing a second photo resist on a surface of a substrate;
placing the grayscale photo mask in close proximity to the second-photo resist;
exposing light onto and through the grayscale photo mask to transfer the modulated ion density contained in the grayscale photo mask into the second photo resist as exposed and unexposed portions;
developing the second photo resist to remove the exposed portions in the second photo resist; and
performing one of etching and ion beam milling to the second photo resist and photo mask blank to obtain the optical grayscale element.

18. A method for producing an optical grayscale element as claimed in claim 17, wherein said exposing light onto and through the grayscale photo mask is performed using one of a mask aligner and stepper.

19. A method for producing an optical grayscale element as claimed in claim 17, wherein the ions used for implantation are selected based on performing said exposing light onto and through the grayscale photo mask using light having a wavelength which is one of 436 nm (G-line), 405 nm (H-line), 365 nm (I-line), 248 nm (KrF excimer laser), 193 nm (ArF excimer laser), and 0.71 nm (X-ray).

20. A method for producing an optical grayscale element as claimed in claim 17, wherein said implanting ions is performed by implanting a dosage of ions in a range of 10¹⁵ to 10¹⁸ atoms/cm².

21. A method for producing an optical grayscale element as claimed in claim 17, wherein said implanting ions is performed by using an incident angle of implantation that is in a range of 5° to 10° with respect to a normal.

22. A method for producing an optical grayscale element as claimed in claim 17, further comprising selecting, as the ion for implantation, an element having at least an atomic number which provides no greater than a maximum allowable RMS radial expansion for achieving a desired resolution of the grayscale photo mask.

23. A method for producing an optical grayscale element, said method comprising:
providing a first photo resist on a surface of a photo mask blank;
exposing grayscale light onto the first photo resist to form a predetermined pattern of exposed and unexposed portions in the first photo resist;
developing the first photo resist to remove the exposed portions in the first photo resist and produce a grayscale photo resist structure;
performing one of ion beam milling and etching to transfer the grayscale photo resist structure into the photo mask blank;
implanting ions into the photo mask blank to obtain a modulated ion density in the photo mask blank;
removing portions of the photo mask blank containing the transferal of the grayscale photo resist structure to produce the grayscale photo mask;
providing a second photo resist on a surface of a substrate;
placing the grayscale photo mask in close proximity to the second photo resist;
exposing light onto and through the grayscale photo mask to transfer the modulated ion density contained in the grayscale photo mask into the second photo resist as exposed and unexposed portions;
developing the second photo resist to remove the exposed portions in the second photo resist; and
performing one of etching and ion beam milling to the second photo resist and photo mask blank to obtain the optical grayscale element.

24. A method for producing an optical grayscale element as claimed in claim 23, wherein said exposing light onto and through the grayscale photo mask is performed using one of a mask aligner and stepper.

25. A method for producing an optical grayscale element as claimed in claim 23, wherein the ions used for implantation are selected based on performing said exposing light onto and through the grayscale photo mask using light having a wavelength which is one of 436 nm (G-line), 405 nm (H-line), 365 nm (I-line), 248 nm (KrF excimer laser), 193 nm (ArF excimer laser), and 0.71 nm (X-ray).

26. A method for producing an optical grayscale element as claimed in claim 23, wherein said implanting ions is performed by implanting a dosage of ions in a range of 10¹⁵ to 10¹⁸ atoms/cm².

27. A method for producing an optical grayscale element claimed in claim 23, wherein said implanting ions is performed by using an incident angle of implantation that is in a range of 5° to 10° with respect to a normal.

28. A method for producing an optical grayscale element as claimed in claim 23, wherein said performing etching is by one of a dry etching method and a wet etching method.

29. A method for producing an optical grayscale element as claimed in claim 23, further comprising selecting, as the ion for implantation, an element having at least an atomic number which provides no greater than a maximum allowable RMS radial expansion for achieving a desired resolution of the grayscale photo mask.
